(19) United States
(12) Patent Application Publication
(10) Pub. No.: US 2021/0143248 A1
(43) Pub. Date: May 13, 2021

(54) SEMICONDUCTOR STRUCTURE HAVING LAMINATE DIELECTRIC FILMS AND METHOD OF MANUFACTURING A SEMICONDUCTOR STRUCTURE

(71) Applicant: SEMICONDUCTOR COMPONENTS INDUSTRIES, LLC, Phoenix, AZ (US)

(72) Inventors: Derryl ALLMAN, Camas, WA (US); Diann DOW, Austin, TX (US)

(73) Assignee: SEMICONDUCTOR COMPONENTS INDUSTRIES, LLC, Phoenix, AZ (US)

(21) Appl. No.: 16/682,717

(22) Filed: Nov. 13, 2019

(51) Int. Cl. H01L 49/02

(52) U.S. Cl. CPC H01L 28/40

(57) ABSTRACT

A semiconductor structure includes a region of semiconductor material having a major surface and a first a first insulating structure over the major surface. A first conductive electrode is over the first insulating structure and a laminate film structure is over the first conductive electrode. The laminate film structure includes a first film comprising rutile phase ruthenium dioxide adjacent to the first conductive electrode, and a second film over the first film, wherein the second film comprises a high dielectric constant dielectric material. A second conductive electrode is over the laminate film structure. In some examples, the first film is provided using atomic layer deposition. In some examples, the second film comprises rutile phase titanium dioxide formed using atomic layer deposition. In some examples, the laminate film structure can be used as part of a MIM capacitor.

### CROSS-REFERENCE TO RELATED APPLICATIONS

Not Applicable.

### TECHNICAL FIELD

The present disclosure relates, in general, to electronic structures, and more particularly, to semiconductor structures and methods for manufacturing semiconductor structures.

### BACKGROUND

Capacitors are basic components in certain semiconductor integrated circuit (IC) applications, such as analog, microwave, and radio frequency applications. To meet different purposes of IC applications, various types of capacitors have been used in the past. One type of capacitor structure is a metal-insulator-metal (MIM) capacitor, which has used a single higher dielectric constant (higher k) film or a thin insulating dielectric film sandwiched between opposing metal electrodes. With the trend towards miniaturization of IC circuits, higher dielectric constant films have shown promise; however, the higher the dielectric constant of the film translates into a lower electric field strength, which can result in higher current leakage. Also, the use of the single insulating dielectric film has not allowed for adjustment of multiple electric field properties of the MIM capacitor to improve characteristics, such as linearity. In addition, the use of MIM capacitors with certain types of metal interconnect technologies has resulted in manufacturing problems, such as reduced control of etch processes (e.g., over-etching problems), which can damage the lower metal electrode and/or deposit material from the lower metal electrode on sidewalls of the MIM capacitor. These problems have resulted in increased leakage and other reliability issues. Previous attempts to address these issues have led to an increase in manufacturing steps and costs, and the resultant MIM capacitor structures still have had performance and reliability problems.

Accordingly, it is desired to have structures, including capacitor structures, and methods of forming such structures that overcome the issues associated with prior structures and methods. It would be beneficial for the structures and methods to be cost effective and to be easily integrated into existing semiconductor device process flows.

### BRIEF DESCRIPTION OF THE DRAWINGS

FIG. 1 illustrates a partial section view of a semiconductor structure in accordance with the present description;

FIGS. 2, 3, 4, 5, 6, 7, and 8 illustrate partial sectional views of a semiconductor structure at various steps in fabrication in accordance with the present description;

FIG. 9 illustrates a partial sectional view of a semiconductor structure in accordance with the present description;

FIG. 10 illustrates a partial sectional view of a semiconductor structure in accordance with the present description;

FIG. 11 illustrates a partial sectional view of a semiconductor structure in accordance with the present description;

FIG. 12 illustrates a partial sectional view of a semiconductor structure in accordance with the present description;

FIG. 13 illustrates a partial sectional view of a semiconductor structure in accordance with the present description;

FIG. 14 illustrates a partial sectional view of a semiconductor structure in accordance with the present description;

FIG. 15 illustrates a partial sectional view of a semiconductor structure in accordance with the present description;

FIG. 16 illustrates a partial sectional view of a semiconductor structure in accordance with the present description;

FIGS. 17 and 18 are graphs showing electrical results for semiconductor structures in accordance with the present description;

FIGS. 19, 20, 21, 22, 23, and 24 illustrate partial sectional views of a semiconductor structure at various steps of fabrication in accordance with the present description;

FIG. 25 illustrates a partial sectional view of a semiconductor structure in accordance with the present description;

FIG. 26 illustrates a partial sectional view of a semiconductor structure in accordance with the present description; and

FIG. 27 illustrates a partial sectional view of a semiconductor structure in accordance with the present description.

For simplicity and clarity of the illustration, elements in the figures are not necessarily drawn to scale, and the same reference numbers in different figures can denote the same elements. Additionally, descriptions and details of well-known steps and elements are omitted for simplicity of the description. For clarity of the drawings, certain regions of device structures, such as doped regions or dielectric regions, may be illustrated as having generally straight line edges and precise angular corners. However, those skilled in the art understand that, due to the diffusion and activation of dopants or formation of layers, the edges of such regions generally may not be straight lines and that the corners may not be precise angles. As used herein, the term and/or includes any and all combinations of one or more of the associated listed items. In addition, the terminology used herein is for the purpose of describing particular example embodiments only and is not intended to be limiting of the disclosure. As used herein, the singular forms are intended to include the plural forms as well, unless the context clearly indicates otherwise. It will be further understood that the terms comprises, comprising, includes, and/or including, when used in this specification, specify the presence of stated features, numbers, steps, operations, elements, and/or components, but do not preclude the presence or addition of one or more other features, numbers, steps, operations, elements, components, and/or groups thereof. It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure. Reference to “one example” or “an example” means that a particular feature, structure or characteristic described in connection with the embodiment is included in at least one example of the present invention. Thus, appearances of the phrases “in one example” or “in an example” in various places throughout this specification are not necessarily all referring to the same example, but in some cases it may. Furthermore, the particular features, structures or characteristics may be combined in any suitable manner, as would be apparent to one of ordinary skill in the art, in one or more example embodiments. Additionally, the term while means a certain action occurs at least within some portion of a duration of the initiating action. The use of word about, approximately or substantially means a value of an element is expected to be close to a state value or position. However, as is well known in the art there are always minor variances preventing values or positions from being exactly stated. Unless specified otherwise, as used herein the word over or on includes orientations, placements, or relations where the specified elements can be in direct or indirect physical contact. The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}. It is further understood that the examples illustrated and described hereinafter suitably may have examples and/or may be practiced in the absence of any element that is not specifically disclosed herein. Unless specified otherwise, the term “coupled” may be used to describe physical or electrical coupling of elements that directly contact each other or that are indirectly connected by one or more other elements. For example, if element A is coupled to element B, then element A can be directly contacting element B or indirectly connected to element B by an intervening element C.

### DETAILED DESCRIPTION

The present description includes, among other features, semiconductor structures and associated methods that use a thin film as a first film in a laminate film structure that provides an etch barrier and a beneficial material phase or structure that acts as a template for one or more subsequent films formed on the first film. In some examples, the first film protects the lower metal electrode in a MIM capacitor structure to reduce susceptibility to over-etching and to reduce any deposition of material from the lower metal electrode onto the MIM capacitor structure. In some examples, the first film comprises a rutile phase ruthenium dioxide (RuO₂). In some examples, a second film, which can have a high dielectric constant, is over the first film. In some examples, the second film can comprise rutile phase titanium oxide (TiO₂), which the authors observed experimentally has a lower leakage MIM capacitor applications compared to other dielectric films, and has a higher dielectric constant of approximately 80.

In some examples, one or more additional films can be provided on the second film. The authors observed experimentally that electrically active traps, polarization effects, or contaminates contained within a MIM dielectric film can make the dielectric film susceptible to non-linear capacitance changes relative to applied voltages. In some examples, the additional film(s) can comprise a dielectric(s) that has a non-linearity response opposite to the response of the second dielectric film. More particularly, the additional film(s) can be configured to counterbalance the non-linearity response of the second film to improve non-linearity performance, to increase electric field strength, and/or to reduce leakage current of the MIM capacitor structure. In some examples, the additional film can be one or more of aluminum oxide (Al₂O₃), hafnium oxide (HfO₂), zirconium oxide (ZrO₂), and/or a silicon oxide (SiOₓ).

In other examples, lower dielectric constant (lower k) films can be used in the laminate film structures. In some examples, atomic layer deposition (ALD) is used to provide the first, second, and additional films. MIM capacitors in accordance with the present description can be integrated into semiconductor IC structures and placed at any metal interconnect level and can be combined with other capacitors in the metal level or other metal levels to form a stacked version to increase capacitance values. The MIM structures can be planar and/or trench structures. The laminate film configurations of the present description also can be used in device structures other than capacitors, and can comprise other materials, such as ferroelectric materials, piezoelectric materials, or other materials as known to one of ordinary skill in the art.

In one example, a semiconductor structure includes a region of semiconductor material having a major surface and a first insulating structure over the major surface. A first conductive electrode is over the first insulating structure and a laminate film structure is over the first conductive electrode. The laminate film structure includes a first film comprising rutile phase ruthenium dioxide adjacent to the first conductive electrode, and a second film over the first film, wherein the second film comprises a high dielectric constant dielectric material. A second conductive electrode is over the laminate film structure. In some examples, the first film is provided using atomic layer deposition. In some examples, the second film comprises rutile phase titanium dioxide formed using atomic layer deposition.

In one example, a semiconductor structure includes a region of semiconductor material and a first conductive electrode over the region of semiconductor material. A first insulating structure separates the first conductive electrode from the region of semiconductor material. A laminate film structure is over the first conductive electrode and includes a first film comprising rutile phase ruthenium dioxide adjacent to the first conductive electrode, a second film over the first film, wherein the second film comprises rutile phase titanium dioxide, and a third film over the second film wherein the third film comprises a dielectric material. A second conductive electrode is over the laminate film structure.

In one example, a method of forming a semiconductor structure includes providing a region of semiconductor material having a major surface. The method includes providing a first insulating structure over the major surface and providing a first conductive electrode over the first insulating structure. The method includes providing a laminate film structure over the first conductive electrode, which includes a first film comprising rutile phase ruthenium dioxide adjacent to the first conductive electrode, and a second film over the first film, wherein the second film comprises a high dielectric constant dielectric material. The method includes providing a second conductive electrode over the laminate film structure.

Other examples are included in the present description. Such examples may be found in the figures, in the claims, and/or in the description of the present disclosure.

FIG. 1 illustrates a partial sectional view of an electronic structure, such as a semiconductor structure 10 in accordance with the present description. In some examples, semiconductor structure 10 includes a region of semiconductor material 11 having a major surface 18. In some examples, region of semiconductor material 11 can be silicon, combinations of silicon with other Group IV elements, other IV-IV materials, III-V materials, semiconductor-on-insulator (SOI) materials, other materials as known to one of ordinary skill in the art, or combinations thereof. In some examples, region of semiconductor material 11 can comprises a base substrate and one or more epitaxial layers disposed over the base substrate.

Semiconductor structure 10 can be an integrated circuit device, such as an application specific integrated circuit (ASIC) device, a memory device, a controller device, a power device, a signal processing device, a microprocessor device, a microcontroller device, a sensor device, an optical device, or other devices as known to one of ordinary skill in the art including combinations of these devices. Region of semiconductor material 11 typically includes doped regions, isolation regions, control structures, interconnect regions or structures, and other regions or structures, which are not illustrated so as to not distract from the present description. It is understood that different types of semiconductor devices have different topographies and structures proximate to major surface 18, and that the present description is applicable to such topographies and structures including derivatives thereof as well as to other configurations.

Semiconductor structure 10 further includes an insulating structure 21, such as a first insulating structure 21 over major surface 18 of region of semiconductor material 11. In some example, insulating structure 21 comprises one or more layers of dielectric material, such an oxide, a nitride, a doped oxide, a low k material, other materials as known to one of ordinary skill in the art, or combinations thereof. In some examples, an upper surface of insulating structure 21 can be planarized using chemical mechanical polishing (CMP) techniques or other techniques as known to one of ordinary skill in the art. Insulating structure 21 is configured, for example, to electrically isolate and protect structures disposed proximate to region of semiconductor material 11.

In some examples, a conductive electrode 23, such as a first conductive electrode 23 is over insulating structure 21. In some examples, conductive electrode 23 comprises one or more layers of conductive material, such as metal materials. In some examples, conductive electrode 23 comprises a first conductive layer 230, a second conductive layer 231 over first conductive layer 230, a third conductive layer 232 over second conductive layer 231, and a fourth conductive layer 233 over third conductive layer 232. In some examples, first conductive layer 230 can be a titanium layer, second conductive layer 231 can be a titanium nitride layer, third conductive layer 232 can be an aluminum or an aluminum alloy layer, and fourth conductive layer 233 can be a titanium nitride layer. In other examples, more or less layers can be used and different materials can be used, and it is understood that the materials described above are non-limiting to the present description. In some examples, conductive electrode 23 can be formed using evaporation, sputtering, chemical vapor deposition (CVD), plating, or other processing techniques as known to one of ordinary skill in the art. Conductive electrode 23 can be patterned using photolithography and etch techniques. Photolithography techniques include, for example, patterned photoresist layers or structures.

In accordance with the present description, semiconductor structure 10 further includes a laminate film structure 26, which in some examples is over conductive electrode 23. More particularly, laminate film structure 26 includes a first film 260, which is adjacent to conductive electrode 23, a second film 261 over first film 260, and in some examples, a third film 262 over second film 261. In some examples, additional films can be included in laminate film structure 26. In some examples, first film 260 adjoins conductive electrode 23 and second film 261 is deposited directly onto first film 260 without any intervening films.

In accordance with the present description, first film 260 is configured to set the phase or structure of second film 261, and in some examples is configured to protect conductive electrode 23 during, for example, etch processes used to form portions of laminate film structure 26 or other structures above and/or including conductive electrode 23. In addition, first film 260 is configured to help preserve the dielectric integrity of second film 261 over time. In some examples, first film 260 comprises a rutile phase ruthenium dioxide, which is a conductive film and can be used as a protective film in the presence of certain process chemistries, such as those including chlorine. In some examples, first film 260 has a thickness in a range from about 20 Angstroms to about 650 Angstroms. In some examples first film 260 is formed using atomic layer deposition (ALD) techniques.

ALD is a method for depositing a material onto an underling structure, such as a semiconductor substrate in as in the case of the present example, a conductive structure. Typically, the deposition occurs a single atomic layer at time using a temperature (e.g., ambient to about 400 degrees Celsius) that is relatively lower compared to other semiconductor deposition processes. ALD typically uses sequential self-limiting surface reactions, sometimes referred to as cycles, to achieve more precise thickness control at the Angstrom level. By way of example, across-wafer variability of about two (2) Angstroms for three (3) sigma can be achieved for a 100 Angstrom ruthenium dioxide film. Because ALD uses self-limiting reactions, ALD provides improved step coverage over underlying structures and is beneficially conformal on high aspect ratio structures, such as the surfaces of trench structures. In addition, ALD processing is compatible with standard semiconductor process flows and can be incorporated into such flows without impacting other semiconductor process steps or underlying structures or features that are temperature sensitive. In some examples, plasma-assisted ALD techniques are used, which is an energy-enhanced technique where a plasma is employed during a step of the cyclic deposition process.

In some examples, second film 261 comprises a rutile phase titanium dioxide formed using ALD techniques. In accordance with the present example, first film 260 comprising rutile phase ruthenium dioxide is used as a template during the ALD film growth to provide the rutile phase titanium dioxide for second film 261. In other examples, other deposition techniques, such as plasma-enhanced chemical vapor deposition (PECVD) can be used to form second film 261. In some examples, the thickness of second film 261 is selected to provide desired capacitance density of laminate film structure 26 when laminate film structure 26 is part of a MIM capacitor 30 in accordance with the present description.

In accordance with the present description, third film 262 can be configured to tune the capacitance of laminate film structure 26 when laminate film structure 26 is part of MIM capacitor 30. In some examples, third film 262 can be one or more of aluminum oxide (Al₂O₃), hafnium oxide (HfO₂), zirconium oxide (ZrO₂), a silicon oxide (SiOₓ), and/or other materials as known to one of ordinary skill in the art. In other examples, lower dielectric constant (lower k) films can be used as part of laminate film structure 26. In some examples, third film 262 can be formed using ALD techniques. When ALD techniques are used to form first film 260, second film 261, and third film 262, manufacturing cycle time and the number of wafer transfer steps can be decreased.

In other examples, third film 262 can be formed using PECVD techniques. Similar to second film 261, the thickness of third film 262 is selected to provide desired capacitance density of laminate film structure 26 when laminate film structure 26 is part of MIM capacitor 30. The authors observed through experimentation that titanium dioxide can have non-linear capacitance density changes relative to applied voltages, which is believed to be caused by electrically active traps, polarization, or contaminates contained within the film. The authors further observed that the non-linear capacitance density changes relative to applied voltage for films, such as Al₂O₃ or SiO₂ are opposite to that of titanium dioxide, and thus, third film 262 can be included to counterbalance the capacitance response of second film 261.

In some examples, semiconductor structure 10 further includes a conductive electrode 24, such as a second conductive electrode 24, over laminate film structure 26. In some examples, conductive electrode 24 is adjacent to third film 262 and is configured as a top electrode for MIM capacitor 30. In some examples, conductive electrode 24 can comprise a metal material, such as one or more of titanium, titanium nitride, tantalum nitride, aluminum, an aluminum alloy, or other materials as known to one of ordinary skill in the art. Conductive electrode 24 can be formed using evaporation, sputtering, or other deposition processes as known to one of ordinary skill in the art. Conductive electrode 24 can have a thickness in range from about 300 Angstroms to about 1400 Angstroms. In accordance with the present example, conductive electrode 23, laminate film structure 26, and conductive electrode 24 are configured as MIM capacitor 30.

In some examples, conductive electrode 23 has a width 23A, first film 260 has a width 260A, second film 261 has a width 261A, third film 262 has a width 262A, and conductive electrode 24 has a width 24A. As illustrated in FIG. 1, width 260A can be different than width 261A and width 262A. In some examples, width 260A is wider than width 261A and width 262A. In some examples, width 260A and width 23A are substantially similar. In this way, first film 260 can be configured as a protective layer for conductive electrode 23 during certain processing steps, such as etching steps. This is an advantage over prior structures and functions to reduce susceptibility to over-etching and to reduce any deposition of material from conductive electrode 23 onto MIM capacitor 30.

In some examples, an insulating structure 210 is over MIM capacitor 30 and can comprise one or more layers of dielectric material, such as an oxide, a nitride, a doped oxide, a low k dielectric, other materials as known to one of ordinary skill in the art, or combinations thereof. In some examples, insulating structure 210 can be planarized using CMP techniques or other techniques as known to one of ordinary skill in the art. Insulating structure 210 is configured to electrically isolate and protect structures disposed proximate to and above insulating structure 21.

In some examples, a conductive via 28, such as a first conductive via 28 extends through a portion of insulating structure 210 to provide an electrical contact to conductive electrode 23. A conductive via 29, such as a second conductive via 29 extends through another portion of insulating structure 210 to provide an electrical contact to conductive electrode 24. In some examples, conductive vias 28 and 29 comprise a trench or via 31, an adhesion layer 32, a barrier layer 33, and a fill layer 34. In some examples, adhesion layer 32 can comprise titanium, barrier layer 33 can comprise titanium nitride, and fill layer can comprise tungsten. In other examples, other materials as known to one of ordinary skill in the art can be used. Adhesion layer 32, barrier layer 33, and fill layer 34 can be formed using evaporation, sputtering, plating, or other processes known to one of ordinary skill in the art. The deposited layers can be planarized after they are formed using, for example, CMP techniques.

In some examples, a conductive interconnect layer 36 is connected to conductive via 28 and a conductive interconnect layer 37 is connected to conductive via 29. In some examples, conductive interconnect layers 36 and 37 can comprise similar materials to conductive electrode 23. In other examples, conductive interconnect layers 36 and 37 can comprise different materials. In some examples, an insulating structure 211 is over conductive interconnect layers 36 and 37, and can comprise one or more layers of dielectric material, such an oxide, a nitride, a doped oxide, a low k dielectric, or other materials as known to one of ordinary skill in the art. In some examples, insulating structure 211 can be planarized using CMP techniques or other techniques as known to one of ordinary skill in the art. Insulating structure 211 is configured to electrically isolate and protect structures disposed proximate to insulating structure 210. It is understood that additional interconnect structures and insulating structures can be added to semiconductor structure 10. Semiconductor structure 10 is an example where conductive vias 28 and 29 contact MIM capacitor 30 from an upper level interconnect layer.

FIGS. 2, 3, 4, 5, 6, 7, and 8 illustrate partial sectional views of a semiconductor structure at various steps in fabrication in accordance with the present description. In some examples, the method of FIGS. 2-8 can be used to form semiconductor structure 10 of FIG. 1. For purposes of the present description, reference to semiconductor structure 10 will be used as an example. It is understood and one or more the steps described can be used to form other semiconductor structures in accordance with the present description.

FIG. 2 illustrates a partial sectional view of semiconductor structure 10 at an intermediate step in fabrication. In some examples, active devices (not shown) have been provided in and over region of semiconductor material 11 proximate to major surface 18. Insulating structure 21 is over major surface 18 and can comprise materials as described previously. Insulating structure 21 can be formed using thermal processes, CVD, PECVD, or other processes as known to one of ordinary skill in the art. In some examples, insulating structure 21 can be planarized using CMP techniques. One or more conductive layers are then provided over insulating structure 21 for a conductive electrode, such as conductive electrode 23. In some examples, multiple conductive layers can be provided, including, for example first conductive layer 230, second conductive layer 231, third conductive layer 232, and fourth conductive layer 233. In other examples, more or less conductive layers can be used. Conductive layers 230-233 can be materials as described previously, and can be formed using evaporation, sputtering, CVD, plating, or other processes as known to one of ordinary skill in the art. The thickness of each of the conductive layers can be selected in accordance with applicable design rules for the process flow selected.

FIGS. 3 and 4 are partial sectional views illustrating semiconductor structure 10 after additional processing. In accordance with the present invention, FIGS. 3 and 4 illustrate the formation of a laminate film structure, such as laminate film structure 26. First film 260 is provided over conductive electrode 23. In some examples, first film 260 is on fourth conductive layer 233 of conductive electrode 23 as illustrated in FIG. 3. In accordance with the present example, first film 260 is configured to set the phase or structure of second film 261, and in some examples is configured to protect conductive electrode 23 during, for example, etch processes used to form portions of laminate film structure 26 or other structures above or including conductive electrode 23. In addition, first film 260 is configured to help preserve the dielectric integrity of second film 261 over time. In some examples, first film 260 comprises a rutile phase ruthenium dioxide, which is a conductive film and can be used as a protective film in the presence of certain process chemistries, such as those including chlorine. In some examples, first film 260 has a thickness in range from about 20 Angstroms to about 100 Angstroms. In some examples first film 260 is formed using ALD techniques. In some examples, first film 260 is formed using plasma-assisted ALD techniques.

Typical process temperatures for ALD are below 450 degrees Celsius and process pressures are in the milli-Torr range to promote surface absorption. Precursors or sources for the ALD process can be either gas, liquid or solid. ALD techniques are preferred generally for precision thin, low atom count, film depositions where uniformity and conformal surface coverage is desired; they provide low defectivity, because there is no gas phase reaction to generate particles that would fall onto the surface of the substrate during the process; they provide control of lattice structure for a template of next films; and they provide insitu layering and desired materials at low temperatures which are not available by other means. In addition, in ALD techniques the reduction process removes carbon or carbon molecules from the film, which results in a more pure film than found in PECVD or CVD deposition techniques.

Plasma-assisted ALD techniques with a direct plasma in the ALD chamber provide a more atomically dense film due to ion bombardment to reduce pores in the amorphous film network. Plasma-assisted ALD techniques with an indirect plasma also provides denser films due to a more reactive reactant. The electric field strength of a plasma-assisted ALD film is comparable to a high temperature thermally grown SiO₂ film as measured by electrical breakdown voltage ramping technique.

Second film 261 is then formed over first film 260, and in some examples, comprises rutile phase titanium dioxide. In some examples, second film 261 is formed using ALD techniques. In accordance with the present example, first film 260 comprising rutile phase ruthenium dioxide is used as template during the ALD film growth to provide second film 261 comprising rutile phase titanium dioxide. In other examples, other deposition techniques, such as PECVD can be used to form second film 261 with first film 260 providing rutile phase template for second film 261. In some examples, the thickness of second film 261 is selected to provide a desired capacitance density for laminate film structure 26 when laminate film structure 26 is part of a MIM capacitor 30 in accordance with the present description.

In some examples, third film 262 is formed over second film 261. In accordance with the present description, third film 262 is configured to tune the capacitance of laminate film structure 26 when laminate film structure 26 is part of MIM capacitor 30 illustrated in FIG. 1. In some examples, third film 262 can be one or more of aluminum oxide (Al₂O₃), hafnium oxide (HfO₂), zirconium oxide (ZrO₂), and/or a silicon oxide (SiOₓ) or other materials as known to one of ordinary skill in the art. In other examples, lower k films can be used in laminate film structure 26. In some examples, third film 262 can be formed using ALD techniques. In other examples, third film 262 can be formed using PECVD techniques. Similar to second film 261, the thickness of third film 262 is selected to provide desired capacitance density of laminate film structure 26 when laminate film structure 26 is part of a MIM capacitor 30. In accordance with the present description, third film 262 can be used to counterbalance the capacitance response of second film 261 as illustrated, for example, in FIG. 18, which will be described later.

FIG. 5 illustrates a partial sectional view of semiconductor structure 10 after additional processing. In some examples, one or more conductive layers are formed over third film 262, which can be used to form conductive electrode 24. By way of example, conductive electrode 24 can comprise titanium nitride, tantalum nitride, or other materials as known to one of ordinary skill the art. In some examples, a titanium-nitride layer or titanium-nitride/aluminum layers can be first formed over laminate film structure 26. Conductive layer 24 can be formed using evaporation, sputtering, CVD, plating or other deposition techniques as known to one of ordinary skill in the art. In some examples, conductive layer 24 has thickness sufficient so that a subsequent via etch step does not damage laminate film structure 26. In addition, the bulk resistivity of conductive electrode 24 can be a factor in the quality factor of MIM capacitor 30, which can determine how fast charge is moved in and out of the capacitor. In some examples, tantalum nitride used in conductive electrode 24 was observed experimentally to produce lower leakage and to provide better linearity compared to other materials. In some examples, conductive electrode 24 has a thickness in a range from about 300 Angstroms to about 1400 Angstroms.

FIG. 6 illustrates a partial sectional view of semiconductor structure 10 after further processing. In some examples, photolithography (e.g., patterned photoresist) and etch techniques can be used to define conductive electrode 24, third film 262, and second film 261. Typically, a plasma-etch process with a chlorine chemistry is used, and first film 260 comprising ruthenium dioxide acts as a beneficial etch stop layer to protect conductive electrode 23 at least during this step. The patterned photoresist can then be removed using, for example, a solvent process. Next, photolithography and etch techniques can be used to define first film 260 as illustrated in FIG. 7. In some examples, a fluorine chemistry is used to remove portions of first film 260 comprising ruthenium oxide, and then a chlorine chemistry is used to remove portions of conductive layers 230-233 to define conductive electrode 23. In the present example, this further defines MIM capacitor 30. In some examples, and as illustrated in FIG. 7, conductive electrode 23 extends beyond second film 261, third film 262, and conductive electrode 24 to protect and preserve size of the capacitor. In addition, this lower extension feature allows for a top conductive via electrical connection to conductive electrode 23. In other examples, a bottom conductive via interconnect can be used (see for example, FIG. 10). Since ruthenium oxide has conductive properties, it does not have to be removed from above conducive electrode 23. That is, electrical contact to conductive electrode 23 can be made with first film 260 remaining in place over conductive electrode 23. In other examples, when vias 31 are etched in insulating structure with a fluorine chemistry as described below, the etch step can remove the ruthenium oxide in the via opening to provide a lower contact resistance to conductive electrode 23.

FIG. 8 illustrates a partial sectional view of semiconductor structure 10 after additional processing. In some examples, insulating structure 210 is formed over MIM capacitor 30 and can comprise one or more layers of dielectric material, such an oxide, a nitride, a doped oxide, a low k dielectric, or other materials as known to one of ordinary skill in the art. In some examples, insulating structure 210 can be planarized using CMP techniques or other techniques as known to one of ordinary skill in the art. Insulating structure 210 is configured to electrically isolate and protect structures disposed proximate to and above insulating structure 21 including MIM capacitor 30.

In some examples, conductive via 28 extends through a portion of insulating structure 210 to provide electrical contact to conductive electrode 23. Conductive via 29, extends through another portion of insulating structure 210 to provide electrical contact to conductive electrode 24. In some examples, conductive vias 28 and 29 comprise a trench or via 31, adhesion layer 32, barrier layer 33, and fill layer 34. In some examples, adhesion layer 32 can comprise titanium, barrier layer 33 can comprise titanium nitride, and fill layer can comprise tungsten. Other materials can be used to conductive vias 28 and 29. Vias 31 can be formed using photolithography and etching techniques with a fluorine chemistry. When vias 31 are etched in insulating structure with a fluorine chemistry, the etch step can remove the ruthenium oxide in the via opening to provide a lower contact resistance to conductive electrode 23. Adhesion layer 32, barrier layer 33, and fill layer 34 can be formed using evaporation, sputtering, CVD, plating, or other processes as known to one of ordinary skill in the art. The layers can be planarized after they formed using CMP techniques. In subsequent steps, conductive interconnect layers 36 and 37 can be formed over insulating structure 210 and insulating structure 211 can be formed over interconnect layers 36 and 37 as illustrated in FIG. 1. Is understood that additional interconnect structures can be used in semiconductor structure 10.

FIG. 9 illustrates a partial sectional view of an electronic structure, such as a semiconductor structure 10A in accordance with the present description. Semiconductor structure 10A is similar to semiconductor structure 10 and only certain differences will be described hereinafter. Semiconductor structure 10A is an example where a single MIM capacitor 30 is placed at a metal level just below the top-most interconnect level, which can include conductive interconnect layers 36 and 37. In semiconductor structure 10A, conductive electrode 24 and conductive electrode 23 are contacted from the top side as illustrated in FIG. 9. A passivation layer 212 is provided over conductive interconnect layers 36 and 37 and comprise an oxide, a nitride, or an organic passivation, such as polyimide, combinations thereof or other materials as known to one ordinary skill in the art. Passivation layer 212 is configured to protect interconnect layers 36 and 37 from external elements. Portions of conductive interconnect layers 36 and 37 can be exposed using photolithography and etching techniques to allow for external connections to semiconductor structure 10A.

FIG. 10 illustrates a partial sectional view of an electronic structure, such as a semiconductor structure 10B in accordance with the present description. Semiconductor structure 10B is similar to semiconductor structure 10 and only certain differences will be described hereinafter. In semiconductor structure 10B, electrical connection to conductive electrode 23 of MIM capacitor 30 is made from a metal interconnect layer below conductive layer 23, which can be covered by an insulating structure 21A. In some examples, insulating structure 21A can comprise similar materials to insulating structure 21 and can be formed using similar processes. In some examples, a conductive via 28A electrically connects conductive electrode 23 to a conductive interconnect layer 36A. In some examples, conductive interconnect layer 36A can comprise materials similar to conductive interconnect layer 36, and conductive via 28A can comprise materials similar to conductive via 28.

FIG. 11 illustrates a partial sectional view of an electronic structure, such as a semiconductor structure 10C in accordance with the present description. Semiconductor structure 10C is similar to semiconductor structure 10 and semiconductor structure 10B and only certain differences will be described hereinafter. More particularly, semiconductor structure 10C is an example of a semiconductor structure having a plurality of MIM capacitors (i.e., two or more) in a stacked configuration. Semiconductor structure 10C comprises MIM capacitor 30 disposed within insulating structure 210 and a MIM capacitor 30A disposed within insulating structure 21A below MIM capacitor 30. Conductive via 29A electrically connects conductive electrode 23 of MIM capacitor 30 to a conductive electrode 24A of MIM capacitor 30A. In some examples, conductive via 29A can comprise similar materials as conductive via 29, and conductive electrode 24A can comprise similar materials to conductive electrode 24.

Similar to MIM capacitor 30, MIM capacitor 30A comprises a laminate film structure 26A, which includes first film 260 comprising ruthenium oxide and second film 262 comprising titanium dioxide as described previously. In some examples, laminate film structure 26A further includes third film 262 as described previously. MIM capacitor 30A further includes a conductive electrode 23A, which can be similar to conductive electrode described previously. Conductive electrodes 23 and 23A can be electrically connected to another conductive via (not shown) either from above or from below. It is understood that the sizes and thickness of films 260-262 can be the same or different so that MIM capacitor 30 can have similar or different capacitance characteristics compared to MIM capacitor 30A. MIM capacitor 30A can be formed using processes as described previously. MIM capacitors 30 and 30A are examples of planar-type capacitor structures.

FIG. 12 is a partial sectional view of an electronic structure, such as a semiconductor structure 10D in accordance with the present description. Semiconductor structure 10D is similar to semiconductor structure 10, but is configured with a different metallization scheme. In particular, semiconductor structure 10D is configured for copper interconnects, such as a dual damascene copper configuration. Similar to semiconductor structure 10, semiconductor structure 10D includes MIM capacitor 30 comprising laminate film structure 26 having first film 260 comprising ruthenium oxide over a conductive electrode 230 and second film 231 comprising titanium dioxide. In some examples, laminate film structure 26 further includes third film 262 as described previously. A conductive via comprising, for example, a dual damascene conductive via 280 provides electrical connection to conductive electrode 230 of MIM capacitor 30, which can comprise a metal such as tantalum nitride or other conductive materials as known to one of ordinary skill in the art.

A conductive via comprising, for example, a dual damascene conductive via 290 provides electrical connection to conductive electrode 24 of MIM capacitor 30. In some examples, conductive vias 280 and 290 include adhesion layer 32, barrier layer 33, and fill layer 34. In semiconductor structure 10D, adhesion layer 32 is provided on surfaces of dual via 310 and can comprise tantalum or other materials as known to one of ordinary skill in the art. Barrier layer 33 can comprise tantalum nitride or other materials as known to one of ordinary skill in the art. In the present example, fill layer 34 can comprise copper. Adhesion layer 32 and barrier layer 33 can be formed using evaporation, sputtering, CVD, or other deposition techniques as known to one of ordinary skill in the art. Fill layer 34 can be formed using evaporation, sputtering, CVD, plating, combinations thereof, or other deposition techniques as known to one of ordinary skill in the art. Planarization techniques, such as CMP can be used to planarized conductive vias 280 and 290 so that their upper surfaces a substantially coplanar with insulating structure 210 as generally illustrated in FIG. 12.

Is some examples, layers 41B and 43B are formed over insulating structure 210 and conductive vias 280 and 290. Layers 41B and 43B may be referred to as a protective structure. In some examples, layer 41B comprises silicon carbide. In other examples, nitrogen can be added to the silicon carbide layer. In some examples, layer 41B comprises silicon-carbide. In some examples, layer 43B comprises a dielectric material, such as a deposited oxide material. In some examples, insulating structure 211 is formed over layer 43B. It is understood that other metal interconnect layers can be provided electrically connected to conductive vias 280 and 290, which can be covered by insulating structure 211. Layers 41B and 43B can be formed using ALD, PECVD, or other deposition processes as known to one of ordinary skill in the art and can be patterned to allow for electrical connections. Layers 41B and 43B can have thicknesses in a range from about 10 Angstroms to about 500 Angstroms.

In some examples, semiconductor structure 10D comprises conductive interconnect layers 46 and 47 disposed within insulating structure 21 below MIM capacitor 30. In some examples, conductive interconnect layers 46 and 47 comprise copper interconnects with thin layers of tantalum nitride and tantalum below the copper portion. Conductive interconnect layers 46 and 47 can be separated from conductive electrode 230 by layers 41A and 43A, which can comprise similar materials to layer 41B and 43B respectively. Semiconductor structure 10D is an example of a structure where conductive electrode 230 of MIM capacitor 30 is disposed above a lower metal interconnect layer, and electrical connection to conductive electrode 230 is from an above. In addition, it is not necessary for conductive electrode 230 to reside above or cover a lower metal interconnect layer.

FIG. 13 is a partial sectional view of an electronic structure, such as a semiconductor structure 10E in accordance with the present description. Semiconductor structure 10E is similar to semiconductor structure 10 and semiconductor structure 10D, and only certain differences will be described herein. In semiconductor structure 10E, a conductive via 281 comprises an elongated via that is electrically connected to conductive interconnect layer 46. More particularly, conductive via 281 extends through first film 260, layer 43A, and 41A to connect with conductive interconnect layer 46. As illustrated in FIG. 13, conductive via 281 configured as an elongated via makes contact to side surface 260B of first film 260, top surface 230B of conductive electrode 230, and side surface 230C of conductive electrode 230. Semiconductor structure 10E is an example of a structure where conductive electrode 230 of MIM capacitor 30 to connected to conductive interconnect layer 46, which is a lower metal interconnect layer using an elongated conductive via 281. This allows conductive electrode 230 to be electrically connected at two different metal levels (e.g., one from below, and one from above MIM capacitor 30).

FIG. 14 is a partial cross-sectional view of an electronic structure, such as a semiconductor structure 10F in accordance with the present description. Semiconductor structure 10F is similar to semiconductor structure 10D and semiconductor structure 10E, and is configured with a plurality of MIM capacitors in a stacked capacitor configuration. In some examples, semiconductor structure 10F comprises MIM capacitor 30 and MIM capacitor 30A. It understood that additional MIM capacitors can be included. Conductive via 290A is electrically connected to conductive electrode 24A of MIM capacitor 30A, which includes laminate film structure 26A having first film 260 comprising rutile phase ruthenium dioxide and second film 261 comprising rutile phase titanium dioxide. Conductive via 280 is electrically connected to conductive electrode 230A of MIM capacitor 30A. In some examples, conductive via 281 comprising an elongated via is electrically to conductive electrode 230 of MIM capacitor 30 and extends through layers 41B and 43B to electrically connect to conductive via 280 In some examples, layer 41C and layer 43C over provided over insulating structure 211 and conductive vas 281 and 290 and can comprise similar material as layer 41A and 43A respectively. An insulating structure 213 can be provided over layer 41C and 43C and can comprise similar materials as insulating structure 21. Semiconductor structure 10F is an example, of a stacked capacitor configuration using a conductive via with an elongated via structure (e.g., conductive via 281). The elongated via can electrically connect to either the bottom electrode (e.g., conducive electrode 230A) of MIM capacitor 30A as illustrated in FIG. 14, or it can electrically connect to the top electrode (e.g., conductive electrode 24A) of MIM capacitor 30A in other examples.

FIG. 15 illustrates a partial sectional view of an electronic structure, such as a semiconductor structure 10G in accordance with the present description. In some examples, semiconductor structure 10G includes conductive interconnect layer 47 that is electrically connected to conductive electrode 230 of MIM capacitor 30. Semiconductor structure 10G is an example, where the lower electrode (e.g., conductive electrode 230) of MIM capacitor 30 is electrically connected to a lower level metal interconnect (e.g., conductive interconnect layer 47). In some examples, conductive interconnect layer 47 can include a layer 470A comprising tantalum, a layer 470B comprising tantalum nitride, and a layer 470C comprising copper. In some examples, conductive electrode 230 can comprise tantalum. In some examples, layer 41A and layer 43A are provided to cover portions of conductive interconnect layer 47 and to cover side surfaces and the upper surface of MIM capacitor 30 as generally illustrated in FIG. 15. In this configuration, conductive electrode 230, first film 260, second film 261, third film 262, and conductive electrode 240 can be formed in a single patterned photoresist and etch step, which saves on manufacturing costs and cycle time.

FIG. 16 illustrates a partial sectional view of an electronic structure, such as a semiconductor structure 10H in accordance with the present description. Semiconductor structure 10H is similar to semiconductor structure 10F and 10G and only certain differences will be described hereinafter. Semiconductor structure 10H is configured with a plurality of MIM capacitors in a stacked capacitor configuration. In some examples, semiconductor structure 10H comprises a stacked capacitor version of semiconductor structure 10G. In some examples, semiconductor structure 10H comprises MIM capacitor 30 and MIM capacitor 30A as described previously with both having first film 260 comprising rutile phase ruthenium dioxide and second film 261 comprising rutile phase titanium dioxide. In some examples, third film 262 as described previously is included. It understood that additional MIM capacitors can be included.

In semiconductor structure 10H, conductive via 290A is electrically connected to conductive electrode 24A of MIM capacitor 30A. In some examples, conductive interconnect layer 47 is electrically connected to conductive electrode 230A of MIM capacitor 30A, and layers 41A and 43A cover portions of conductive interconnect layer 47 and MIM capacitor 30A. Conductive via 290A is further electrically connected to conductive electrode 230 of MIM capacitor 30. Conductive via 290 is electrically connected to conductive electrode 24 of MIM capacitor 30. In some examples, layers 41B and 43B cover portions of fill layer 34 and portions of MIM capacitor 30. In some examples, layer 41C and 43C are over insulating structure 211 and conductive via 390 and insulating structure 213 is over layer 43C as generally illustrated in FIG. 16.

It is understood that in accordance with the present description, the MIM capacitors can be combined to provide any number of examples within the scope of the present description.

FIG. 17 is a graph showing capacitance densities of a MIM capacitor 30 compared to a prior MIM capacitor. The capacitance densities were obtained from capacitance voltage measurements at 100 kilo-hertz (kHz) with ALD deposited films annealed in forming gas at approximate 400 degrees Celsius. Line 171 corresponds to MIM capacitor 30 having first film 260 comprising rutile phase ruthenium dioxide and second film 261 comprising rutile phase titanium dioxide with a combined thickness of about 210 Angstroms. Line 172 corresponds to a MIM capacitor with anatase phase titanium dioxide with a thickness of about 160 Angstroms. The titanium dioxide in both examples was formed using 400 cycles in the ALD process. Typically, one cycle in an ALD process corresponds to a first introduction of an oxidant reactant that physically absorbs onto the surface where the film is to be deposited, then the ALD chamber is evacuated of the oxidant gas. Next, the reactant gas is introduced that physically absorbs onto the surface and reacts to grow a monolayer of the film. Afterward, the chamber is evacuated again.

MIM capacitor 30 was found to have quadratic voltage coefficients of capacitance (VCC), alpha, of about −35000 ppm/V² and the dielectric constant of the titanium dioxide was about 89 indicating that the titanium dioxide film in MIM capacitor 30 was in the desired rutile phase. This was further confirmed using X-ray powder diffraction (XRD) analysis. The MIM capacitor with titanium dioxide only was found to have quadratic voltage coefficients of capacitance of about +29000 ppm/V² and the dielectric constant of the titanium dioxide was about 52 indicating that the titanium dioxide was in the less desired anatase phase.

FIG. 18 is a graph showing capacitance densities for MIM capacitors 30 with first film 260 comprising ruthenium dioxide having a thickness of about 100 Angstroms, second film 261 comprising titanium dioxide, and third film 262 comprising an aluminum oxide. All three films were formed using ALD with 250 cycles (c) used to form first film 260 and 400 cycles used to form second film 261. Line 181 is for third film 262 comprising Al₂O₃ formed using 70 cycles, line 182 is for third film 262 comprising Al₂O₃ formed using 75 cycles, and line 183 is for third film 262 comprising Al₂O₃ formed using 80 cycles. As shown in FIG. 18, the linearity of the capacitance density can be adjusted by increasing the thickness of third film 262. In addition, the capacitance density can be kept constant by decreasing the thickness of second film 261. As illustrated in FIG. 18, MIM capacitors 30 were obtained with capacitance densities from about 10 fF/μ² to about 18 fF/μm².

FIG. 19 illustrates a partial sectional view of an electronic structures, such as a semiconductor structure 10J in accordance with the present description. Semiconductor structure 10J comprises MIM capacitor 30B configured as a trench MIM capacitor in accordance with the present description. In some examples, MIM capacitor 30B is within a via 61A or a trench 61A formed within insulating structure 211. In the present example, via 61A extends to conductive electrode 23, which forms the bottom electrode for MIM capacitor 30B. In some examples, laminate film structure 26 is disposed over sidewall and bottom surfaces of via 61A and includes first film 260 and second film 261. In some examples, third film 262 is included. In accordance with the present description, first film comprise rutile phase ruthenium dioxide as described previously, and second film 261 comprise rutile phase titanium dioxide.

In some examples, conductive electrode 24 includes adhesion layer 32, barrier layer 33, and fill layer 34 as described previously, and is configured as the top electrode for MIM capacitor 30B. Conductive interconnect layer 37 can be electrically connected to conductive electrode 24 and can be covered by insulating structure 213 described previously.

Semiconductor structure 10J further includes a conductive via 28B within insulating structure 211, which electrically connects an upper conductive interconnect layer 38 within insulating structure 213 to a lower conductive interconnect layer 39 within insulating structure 211 below conductive via 28B. In some examples, conductive interconnect layers 37, 38, and 39 can comprise materials similar to those used for conductive electrode 23. In accordance with the present description, conductive via 28B comprises a via 61B or a trench 61B disposed within insulating structure 211, and first film 260, second film 261, and third film 262 disposed along sidewall surfaces and a portion of the bottom surface of via 61B. In the present example, at least adhesion layer 32 extends through first film 260, second film 261, and third film 262 proximate to the bottom surface of via 61B to electrically connect to conductive interconnect layer 39. In some examples, a conductive via 29 comprising via 31, adhesion layer 32, barrier layer 33, and fill layer 34 can electrically connect conductive electrode 23 to a lower conductive interconnect layer 36B within insulating structure 210. Conductive interconnect layer 36B can comprise materials similar to those used for conductive electrode 23.

FIGS. 20, 21, 22, 23, and 24 illustrate partial sectional views of a semiconductor structure at various steps of fabrication in accordance with the present description. In some examples, the method of FIGS. 20-24 can be used to form semiconductor structure 10J of FIG. 19. For purposes of the present description, reference to semiconductor structure 10J will be used as an example. It is understood that one or more of the steps described can be used to form other semiconductor structures in accordance with the present description.

FIG. 20 illustrates a partial sectional view of semiconductor structure 10J at an intermediate step in fabrication. In some examples, active devices (not shown) have been provided in and over region of semiconductor material 11 proximate to major surface 18. Insulating structure 21 is over major surface 18, can comprise materials as described previously, and can be formed using processes as described previously. Conductive interconnect layer 36B can be formed over insulating structure 21, and in some examples, can comprise a plurality of conductive layers, such as titanium, titanium-nitride, aluminum (or an aluminum alloy), and titanium nitride. Conductive interconnect layer 36B can formed using evaporation, sputtering, CVD, other processes as known to one of ordinary skill in the art. Photolithography and etching techniques can be used to then pattern conductive interconnect layer 36B.

Insulating structure 210 can be formed over conductive interconnect layer 36B as described previously, and then photolithography and etching techniques can be used to form via 31 extending from an upper surface of insulating structure 210 to conductive interconnect layer 36B. Layers 31, 32, 33, and 34 can then be formed within via 31A and over insulating structure 210. The layers can then be planarized using, for example, CMP techniques to provide conductive via 29. Conductive electrode 23 and conductive interconnect layer 39 can then be formed over insulating structure 210 using, for example, materials and processes previously described. Next, insulating structure 211 can be formed over conductive electrode 23 and conductive interconnect layer 39. Insulating structure 211 can comprise a dielectric material, such as an oxide, a nitride, a doped oxide, a low k dielectric, or other materials as known to one of ordinary skill in the art. In some examples, insulating structure 211 can be planarized using CMP techniques or other techniques as known to one of ordinary skill in the art.

Vias 61A and 61B can then be formed within insulating structure 211 above or proximate to conductive electrode 23 and conductive interconnect layer 39 respectively using, for example, photolithography and etching techniques.

Next, laminate film structure 26 is formed within vias 61A and 61B and over an upper surface of insulating structure 211. In accordance with the present description, first film 260 is formed adjacent to sidewall surfaces of vias 61A and 61B and adjacent to conductive electrode 23 and conductive interconnect layer 39. In accordance with the present description, first film 260 comprises rutile phase ruthenium dioxide and is formed using ALD techniques as described previously. In some examples, first film 260 has a thickness in a range from about 20 Angstroms to about 100 Angstroms. Second film 261 is then formed over first film 260. In some examples, second film 261 comprises rutile phase titanium dioxide and is formed using ALD techniques as described previously. In some examples, third film 262 is then formed over second film 261. In some examples, third film 262 comprises one or more of aluminum oxide, hafnium oxide, zirconium oxide, and silicon oxide or other materials as known to one of ordinary skill in the art. Third film 262 can formed using ALD techniques as described previously. In some examples, a capping layer can be formed over third film 262 to protect laminate film structure 26 from contamination.

FIG. 21 illustrates a partial sectional view of semiconductor structure 10J after additional processing. In some examples, a masking layer 63 can be used to protect first film 260, second film 261, and third film 262 within via 61A and an etch step can be used to remove portions of first film 260, second film 261, and third film 262 within via 61B. Detecting the removal of laminate film structure 26 along the upper surface of insulating structure 211 can be used as an endpoint detection to determine when the films have cleared within via 61B. This provides an opening 64 proximate to the bottom surface of via 61B to expose layer 260 or a portion of conductive interconnect layer 39. As illustrated in FIG. 21, other portions of first film 260, second film 261, and third film 262 remain within via 61B.

FIG. 22 illustrates a partial sectional view of semiconductor structure 10J after further processing. In some examples, masking layer 63 is removed, and films, such as adhesion layer 32 and barrier layer 33 are formed within via 61A and via 61B. In some examples, adhesion layer 32 comprises titanium and barrier layer 33 comprises titanium nitride. It is understood that other materials can be used. Layers 32 and 33 can be formed using evaporation, sputtering, CVD, or other techniques as known to one of ordinary skill in the art. As illustrated in FIG. 22, adhesion layer 32 and barrier layer 33 are disposed within opening 64 to contact conductive interconnect layer 39. Fill layer 34 can then formed over adhesion layer 32 and barrier 33 to a thickness to fill via 61A and via 61B. In some examples, fill layer 34 comprises tungsten and can be formed using CVD techniques or other techniques as known to one of ordinary skill in the art.

FIG. 23 illustrates a partial sectional view of semiconductor structure 10J after additional processing. In some examples, a planarization process, such as CMP or a plasma etch process, is used to remove layers 32, 33, and 34 from the upper surface of insulating structure 211. This leaves MIM capacitor 30B within via 61A and forms conductive via 28B. In a next step, conductive structure 370 can be formed over insulating structure 211, conductive via 28B and MIM capacitor 30B. In some examples, conductive 370 can comprise one or more layer of metals, such titanium, titanium nitride, and aluminum (or aluminum alloy). A capping layer, such as a titanium nitride can be formed over the aluminum layer. It is understood that other materials can be used. Conductive structure 370 can be formed using evaporation, sputtering, CVD, or other techniques as known to one of ordinary skill in the art. In some examples, a masking layer 363 can then be formed over conductive structure 370.

FIG. 24 illustrates a partial sectional view of semiconductor structure 10J after further processing. In some examples, portions of conductive structure 370 are removed. In some examples, a one or more etch steps are used with masking 363 protecting other portions of conductive structure 370 to form conductive interconnect layers 37 and 38. In subsequent steps, insulating structure 213 can formed over conductive interconnect layers and planarized to provide semiconductor structure 10J as illustrated in FIG. 19. Additional MIM capacitor structures can formed in upper interconnect levels using similar processing as described herein.

In other examples, conductive via 28B can be formed in a separate photolithography step so that conductive via 28B can be provided absent first film 260, second film 261, and third film 263. It is understood that via 61A can have different shapes including an elongated shape. It is understood that via 61A and via 61B can have different shapes.

FIG. 25 illustrates a partial sectional view of an electronic structure, such as a semiconductor structure 10K in accordance with the present description. Semiconductor structure 10K is similar to semiconductor structure 10J and only certain differences will be described herein. Semiconductor structure 10K is an example of a structure that includes a plurality of MIM capacitors in a stacked trench capacitor configuration. More particularly, semiconductor structure 10K an include MIM capacitor 30B and MIM capacitor 30C. In the present example, MIM capacitor 30B is formed in via 61A and MIM capacitor 30C is formed in a via 61C provided within insulating structure 211. In some examples, MIM capacitors 30B and 30C both include laminate film structure 26 comprising first film 260 of rutile phase ruthenium dioxide and second film 261 comprising rutile phase titanium dioxide as described previously.

In some examples, conductive electrode 23A provides a bottom electrode for MIM capacitor 30B and further electrically connects to a conductive electrode 24B configured as a top electrode for MIM capacitor 30C below conductive electrode 23A. In some examples, conductive electrode 24B can comprise adhesion layer 32, barrier 33, and fill layer 34 as described previously. In some examples, conductive electrode 24A, which can include adhesion layer 32, barrier layer 33, and fill layer 34, provides a top electrode for MIM capacitor 30B. In the present example, conductive via 28B electrically connects conductive electrode 23A to conductive interconnect layer 38. In addition, conductive interconnect layer 37 can be formed over MIM capacitor 30B and an insulating structure 214 can cover conductive interconnect layers 37 and 38. Insulating structure 214 can comprise a dielectric materials, such as those described previously for insulating structure 21.

In some examples, conductive electrode 23B within insulating structure 211, provides a bottom electrode for MIM capacitor 30C. Conductive electrode 23B can comprise similar materials to conductive electrode 23A. In some examples, MIM capacitor 30C and conductive electrode 23B are within insulating structure 211. In some examples, conductive via 29 electrically connects conductive electrode 23B to conductive interconnect layer 36B within insulating structure 210 above region of semiconductor material 11. In the present example, MIM capacitor 30B is provided within insulating structure 213 in an orientation that is about perpendicular to MIM capacitor 30C formed in insulating structure 211. It is understood that the MIM capacitors can be disposed parallel to each other or can be oriented differently with respect to each other. It is understood that in semiconductor structure 10K or any of the other stacked MIM capacitor structures, the thicknesses and types of films used in the respective laminate film structures 26 or portions thereof can the same or different and can varied in accordance with desired capacitance requirements.

FIG. 26 illustrates a partial sectional view of an electronic structure, such as a semiconductor structure 10L in accordance with the present description. Semiconductor structure 10L includes a MIM capacitor 30D, which is configured as a trench capacitor. MIM capacitor 30D comprises laminate film structure 26 including first film 260 of rutile phase ruthenium dioxide as described previously, and further includes second film 261 comprising rutile phase titanium dioxide. In some examples, laminate film structure 26 includes third film 262 as described previously. MIM capacitor 30D is formed within via 61A extending into insulating structure 211 above conductive interconnect layer 36A. One difference with MIM capacitor 30D is that conductive electrode 23, which comprises the bottom electrode of MIM capacitor 30D, is also formed within via 61A as generally illustrated in FIG. 26. In addition, portions of laminate film structure 26 and conductive electrode 23 extend outside of via 61A onto a portions of insulating structure 211 proximate to via 61A.

MIM capacitor 30D further includes conductive electrode 24, which is within via 61A and, in some examples, can comprise adhesion layer 32, barrier layer 33, and fill layer 34 as described previously. In some examples, conductive interconnect layer 37 is provided over at least a portion of MIM capacitor 30D. In some examples, conductive electrode 24A in combination with conductive interconnect layer 37 provided a top plate for MIM capacitor 30D. In other examples, adhesion layer 32 and barrier layer 33 can extend laterally over laminate film structure 26 outside of via 61A to also provide a portion of the top plate. In some examples, insulating structure 213 can be provided over those portions of MIM capacitor 30D above insulating structure 211. In some examples, conductive plate 23 is electrically connected to conductive interconnect layer 36A below MIM capacitor 30D, which can be electrically connected to a lower level conductive interconnect layer 36B by conductive via 29 as described previously.

It is understood that conductive electrode 23 as illustrated in FIG. 26 can be included in any of the other trench MIM capacitors described herein. In addition, both trench and planar MIM capacitors can be included in other examples structures including, but not limited to, stacked configurations.

FIG. 27 is a partial sectional view of an electronic structure, such as a semiconductor structure 20 in accordance with the present invention. In some examples, semiconductor structure 20 includes a region of semiconductor material 11 having major surface 18, which can comprise materials as described previously. In addition, it is understood that active device structures can be included proximate to major surface 18. Semiconductor structure 20 includes laminate film structure 26, which includes first film 260 comprising rutile phase ruthenium oxide and second film 261. In some examples, second film 261 comprises rutile phase titanium dioxide. Other high k materials, which have tetragonal structures, can be used in place of the titanium dioxide. The ruthenium oxide can be used as the template with these other films similar to the titanium dioxide example. In some examples, first film 260 and second film 261 can be formed using ALD techniques as described previously. In some examples, laminate film structure 26 includes third film 262 over second film 261. Third film 262 can comprise the materials as described previously or different materials, and can be formed using ALD, CVD, PECVD, or other processing techniques as known to one ordinary still in the art.

Semiconductor structure 20 further includes structure 410 proximate to first film 260 and structure 420 proximate to third film 262 (or second film 261 if third film 262 is not used). Structures 410 and 420 can be conductive materials, semiconductor materials, dielectric materials, or combinations thereof. In some examples, semiconductor structure 20 can be configured as a MIM capacitor, a memory device, a sensor device, or other devices.

In summary, semiconductor structures and associated methods have been described that use a thin film as a first film in a laminate film structure. The laminate film structure provides an etch barrier and a beneficial material phase or structure that acts as a template for one or more subsequent films formed on the first film. In some examples, the first film protects the lower metal electrode in a MIM capacitor structure to reduce susceptibility to over-etching and to reduce any deposition of material from the lower metal electrode onto the MIM capacitor structure. In some examples, the first film comprises a rutile phase ruthenium dioxide. In some examples, a second film, which can have a high dielectric constant, is over the first film. In some examples, the second film can comprise rutile phase titanium oxide. In some examples, one or more additional films can be provided on the second film. In some examples, the additional film(s) can comprise a dielectric(s) that has a non-linearity response opposite to the response of the second dielectric film. More particularly, the additional film(s) can be configured to counterbalance the non-linearity response of the second film to improve non-linearity performance, to increase electric field strength, and/or to reduce leakage current of the MIM capacitor structure. In some examples, the additional film can be one or more of aluminum oxide, hafnium oxide, zirconium oxide, and/or a silicon oxide.

In other examples, lower dielectric constant films can be used in the laminate film structures. In some examples, ALD is used to provide the first, second, and additional films. MIM capacitors in accordance with the present description can be integrated into semiconductor IC structures and placed at any metal interconnect level and can be combined with other capacitors in the metal level or other metal levels to form a stacked version to increase capacitance values. The MIM structures can be planar and/or trench structures. The laminate film configurations of the present description also can be used in device structures other than capacitors, and can comprise other materials, such as ferroelectric materials, piezoelectric materials, or other materials as known to one of ordinary skill in the art.

While the subject matter of the invention is described with specific example steps and example embodiments, the foregoing drawings and descriptions thereof depict only typical examples of the subject matter and are not therefore to be considered limiting of its scope. Other examples and permutations are similarly envisioned. For instance, masking techniques other than patterned photoresists can be used to form the various structures described herein. It is evident that many envisioned alternatives and variations such as those described will be apparent to those skilled in the art.

As the claims hereinafter reflect, inventive aspects may lie in less than all features of a single foregoing disclosed example. Thus, the hereinafter expressed claims are hereby expressly incorporated into this Detailed Description of the Drawings, with each claim standing on its own as a separate example of the invention. Furthermore, while some examples described herein include some, but not other features included in other examples, combinations of features of different examples are meant to be within the scope of the invention and meant to form different examples as would be understood by those skilled in the art.

What is claimed is:

1. A semiconductor structure, comprising:
a region of semiconductor material having a major surface;
a first insulating structure over the major surface;
a first conductive electrode over the first insulating structure;
a laminate film structure over the first conductive electrode comprising:
a first film comprising rutile phase ruthenium dioxide adjacent to the first conductive electrode; and
a second film over the first film, wherein the second film comprises a high dielectric constant dielectric material; and
a second conductive electrode over the laminate film structure.

2. The semiconductor structure of claim 1, wherein:
the second film comprises a rutile phase titanium dioxide.

3. The semiconductor structure of claim 1, wherein:
the laminate film structure further comprises a third film interposed between the second film and second conductive electrode, the third film comprising a dielectric material.

4. The semiconductor structure of claim 3, wherein:
the third film comprises one or more of aluminum oxide, hafnium oxide, zirconium oxide, or, silicon oxide.

5. The semiconductor structure of claim 1, wherein:
the semiconductor structure further comprises:
a second insulating structure over the second conductive electrode; and
a trench disposed within the second insulating structure; and
the laminate film structure is disposed at least in part within the trench.

6. The semiconductor structure of claim 5, wherein:
the first film physically contacts the first conductive electrode within the trench.

7. The semiconductor structure of claim 1, further comprising:
a first conductive via coupled to the first conductive electrode; and
a second conductive via coupled to the second conductive electrode.

8. The semiconductor structure of claim 7, wherein:
the first conductive via a side surface of the first film and is further electrically coupled to a conductive interconnect structure separated from the first conductive electrode.

9. The semiconductor structure of claim 7, wherein:
the first trench electrode physically contacts the first film.

10. The semiconductor structure of claim 1, wherein:
the first conductive electrode has a first width;
the first film has a second width;
the second film has a third width; and
the first width and the second width are greater than the third width.

11. The semiconductor structure of claim 1, further comprising:
a protective structure over the second conductive electrode, the protective structure comprising:
silicon carbide layer; and
a dielectric layer over the silicon carbide layer.

12. A semiconductor structure, comprising:
a region of semiconductor material;
a first conductive electrode over the region of semiconductor material;
a first insulating structure separating the first conductive electrode from the region of semiconductor material;
a laminate film structure over the first conductive electrode comprising:
a first film comprising rutile phase ruthenium dioxide adjacent to the first conductive electrode;
a second film over the first film, wherein the second film comprises rutile phase titanium dioxide; and
a third film over the second film wherein the third film comprises a dielectric material; and
a second conductive electrode over the laminate film structure.

13. The semiconductor structure of claim 12, wherein:
the third film comprises one or more of aluminum oxide, hafnium oxide, zirconium oxide, or, silicon oxide.

14. The semiconductor structure of claim 12, wherein:
the semiconductor structure further comprises:
a second insulating structure over the second conductive electrode; and
a trench disposed within the second insulating structure; and
the laminate film structure is disposed at least in part within the trench.

15. The semiconductor structure of claim 12, wherein:
the first film physically contacts the first conductive electrode within the trench.

16. The semiconductor structure of claim 12, further comprising:
a first conductive via coupled to the first conductive electrode; and
a second conductive via coupled to the second conductive electrode.

17. A method of forming a semiconductor structure, comprising:
providing a region of semiconductor material having a major surface;
providing a first insulating structure over the major surface;
providing a first conductive electrode over the first insulating structure;
providing a laminate film structure over the first conductive electrode comprising:
a first film comprising rutile phase ruthenium dioxide adjacent to the first conductive electrode; and
a second film over the first film, wherein the second film comprises a high dielectric constant dielectric material; and
providing a second conductive electrode over the laminate film structure.

18. The method of claim 17, wherein:
providing the laminate film structure comprises providing the first film and the second film using atomic layer deposition; and
the second film comprises a rutile phase titanium dioxide.

19. The method of claim 17, wherein:
providing the laminate film structure further comprises providing a third film interposed between the second film and second conductive electrode, the third film comprising a dielectric material.

20. The semiconductor structure of claim 19, wherein:
providing the third film comprises providing one or more of aluminum oxide, hafnium oxide, zirconium oxide, or, silicon oxide.
